(19) United States
(12) Patent Application Publication
(10) Pub. No.: US 2012/0032303 A1
(43) Pub. Date: Feb. 9, 2012

(54) Bipolar Junction Transistor Based on CMOS Technology

(76) Inventors: Badih ELKAREH, Bucheon-si (KR); Kyu Ok LEE, Yongin-si (KR); Sang Yong LEE, Incheon (KR)

(21) Appl. No.: 12/916,311

(22) Filed: Oct. 29, 2010

(30) Foreign Application Priority Data
Aug. 5, 2010 (KR) 10-2010-0075624

(51) Int. Cl. H01L 29/73; H01L 21/331

(52) U.S. Cl. 257/587; 438/309; 257/E29.174; 257/E21.379

(57) ABSTRACT

The present invention relates to semiconductor technologies, and more particularly to a bipolar junction transistor (BJT) in a CMOS base technology and methods of forming the same. The BJT includes a semiconductor substrate having an emitter region, a base having a first contact, and a collector having a second contact and a well plug; a first silicide film on the first contact; a second silicide film on the second contact; a first silicide blocking layer on or over the semiconductor substrate between the first and second silicide films, and a second silicide blocking layer on the semiconductor substrate between the first silicide film and the emitter region.

### CROSS REFERENCE TO RELATED APPLICATION

This application claims the benefit of Korean Patent Application No. 10-2010-0075624, filed on Aug. 5, 2010, which is hereby incorporated by reference as if fully set forth herein.

### BACKGROUND OF THE DISCLOSURE

1. Field of the Disclosure

The present invention relates to semiconductor technologies, and more particularly to a bipolar junction transistor (BJT) based on a CMOS technology.

2. Discussion of the Related Art

The CMOS technology has been developed toward a high degree of integration, a high operation performance, and low production costs, enabling the use of CMOS devices in many circuit applications, particularly high frequency circuits.

In the meantime, though the CMOS device has excellent operation characteristics, CMOS devices may not adequately meet characteristics required for certain devices in high frequency circuits, such as a low noise amplifiers (LNA), a voltage control oscillators (VCO), and the like.

Consequently, the bipolar junction transistor (BJT), which has a lower noise level than an MOS transistor, shows a wide range of linear gain, has excellent frequency response characteristics and current driving capability, and can be fabricated on the same chip with the CMOS device for performing special high frequency functions. In this instance, high performance bipolar junction transistors are used for high frequency circuits, and CMOS devices are used for logic circuits.

The bipolar junction transistor has three terminals: an emitter, a base, and a collector. When the bipolar junction transistor is fabricated on a semiconductor substrate, a series of masking steps and ion implantation steps are required, because the emitter, the base, and the collector are preferably formed at different depths.

Accordingly, a BiCMOS technology is typically employed, in which the BJT and the CMOS device are formed simultaneously by adding the BJT to a standard CMOS technology, thereby providing the characteristics of the BJT alongside the CMOS devices for specific functions.

FIG. 1 is a schematic plan view of a bipolar structure used in a related art CMOS technology, and a cross section view of the bipolar structure across a line A-A′ shown in the schematic plan view, wherein “E” denotes the emitter, “B” denotes the base, and “C” denotes the collector.

The structure shown in FIG. 1 illustrates an NPN transistor fabricated on a p-type wafer. A PNP structure similar to that shown in FIG. 1 can be fabricated by appropriate change of dopant profiles.

Referring to FIG. 1, there is a plurality of doping regions provided in an active region for forming the emitter, the base, and the collector therein, and shallow-trench isolation (STI) films 5 are provided at the perimeters of the doping regions for defining the active regions. In the related art structure, there is an STI film 5 between the emitter region 6 and a base contact 8 at a base region 3, and there is also an STI film 5 between the base contact 8 and a collector contact 7 within a well plug 4.

The collector C has a collector contact 7, a well plug 4 having the collector contact 7 formed therein, and a collector region 2. The collector region 2 is a deep well collector, and the well plug 4 makes a connection from the deep well collector region 2 to the collector contact 7. The collector contact 7, the well plug 4, and the collector region 2 have the same conductivity type (e.g., N-type).

The base B has a base contact 8 and a base region 3. A well having the opposite conductivity type from the collector region 2 (e.g., P-type) forms the base region 3, in which the base contact 8 is formed.

The base region 3 also has an emitter region 6 of the emitter E formed therein. The emitter region 6 has the opposite conductivity type from the base region 3 (e.g., N+ type).

Silicide films 9, 10, and 11 are formed over the emitter region 6, the collector contact 7, and the base contact 8, respectively. Silicide films 9, 10, and 11 are formed to completely cover the emitter region 6, the collector contact 7, and the base contact 8, respectively.

The bipolar structure has a top-side insulating film containing metal electrodes 12, 13 and 14, which are electrically connected to the silicide films 9, 11, and 10, respectively. The metal electrodes include an emitter electrode 12 connected to the first silicide film 9 on the emitter region 6, a base electrode 13 connected to the second silicide film 11 on the base contact 8, and a collector electrode 14 connected to the third silicide film 10 on the collector contact 7.

In the forward-active mode, the base-emitter junction is forward biased at a voltage V_{BE}, and a collector-base junction is reverse-biased at a voltage V_{CB}. Almost all of the electrons injected into the base traverse the base width W_{b}, and reach the collector C. The electrons that reach the collector constitute a collector current I_{C}. At the same time, holes are injected into the emitter, and recombine with electrons within the emitter or at the silicon interface with silicide film 9, located on the emitter. The injected holes essentially constitute a base current I_{B}. The ratio I_{C}/I_{B} is the current gain β of the bipolar junction transistor.

The current gain increases in proportion to the collector current and is inversely proportional to the base current. That is, the current gain also increases if the collector current increases and if the base current decreases.

The collector current I_{C} is defined in equation 1, and the base current I_{B} is defined in equation 2, below:

$$\begin{matrix}{I}_{C} = {I}_{n} = {A}_{E} \frac{q {\tilde{D}}_{n} {\tilde{n}}_{i}^{2}}{{\int }_{0}^{{W}_{b}} {N}_{A} d x} ( {e}^{{qV}_{F} / kT} - 1 ) & [ 1 ] \\ {I}_{B} = {I}_{p} = {A}_{E} \frac{q {\tilde{D}}_{p} {\tilde{n}}_{i}^{2}}{{\int }_{0}^{{x}_{E}} {N}_{D} d x} ( {e}^{{qV}_{F} / kT} - 1 ) & [ 2 ]\end{matrix}$$

where:

A_{E}=emitter area

\tilde{D}ₙ=average of electron diffusivity in the base

\tilde{D}ₚ=weighted average of holes diffusivity in the emitter

ñᵢ=weighted average of intrinsic-carrier concentration

N_{A}=position dependent ion concentration in the base

N_{D}=position dependent ion concentration in the emitter

V_{F}=base-emitter forward voltage

k=Boltzmann constant

T=absolute temperature

The “0” in the integral in the denominator of equation 1 represents a depletion boundary in the base at the emitter-base junction, and the term “W_{b}” in the integral in the denominator of equation 1 represents the depletion boundary in the base at the collector-base junction. Therefore, the range of the integral in equation 1 is from the depletion boundary in the base at the emitter-base junction to the depletion boundary in the base at the collector-base junction. Accordingly, the width “W_{b}” is the distance between the above two depletion boundaries. Similarly, the range “0”˜“X_{E}” in the integral of the denominator in equation 2 represents the distance between the emitter-base metallurgical junction and the interface between the emitter region 6 and the silicide 9.

As described in equation 1, the collector current is determined by many parameters. The Gummel number is the value of the denominator in equation 1. The greater the Gummel number becomes, the smaller the collector current and, for a given dopant profile, the Gummel number increases as W_{b} increases.

In conclusion, the collector current can increase when W_{b} decreases, or when the ion concentration of the base (e.g., the concentration of boron) decreases.

The base current is also determined by many parameters, and particularly, by X_{E} which is a position-dependent distance between the emitter-base metallurgical junction and the interface of the emitter and the silicide film 9 on the emitter. The integral in the denominator of equation 2 is the Gummel number in the emitter. For a given emitter profile, the greater X_{E} becomes, the smaller the base current becomes.

In summary, the current gain β, which is a ratio of the collector current to the base current, increases when the base Gummel-number decreases and when the emitter Gummel-number increases.

Though a plurality of vertical NPN or PNP structures have been fabricated in a CMOS technology without added complexity, the current gain β of the structures may be relatively small.

The low gain β of the conventional NPN or PNP BJT structures (e.g., as shown in FIG. 1) makes it less suitable for several circuit applications, such as a band-gap reference circuit. This is because a BJT structure having a gain β exceeding 100 is typically required for special applications, such as the band-gap reference circuit.

The related art BJT structure, is limited in that the gain β is smaller than that required for an efficient band-gap reference circuit. To be used as an efficient bandgap reference, a BJT structure fabricated in a CMOS-base technology without added complexity should have a high gain β and also use profiles of the base and the emitter that can be provided by CMOS process.

Therefore, when incorporating a BJT structure in a CMOS process, a scheme is required in which the current gain β (the ratio of the collector current to the base current) is increased without a change in the profiles of the base and emitter that are provided by CMOS technology.

An additional drawback of the related art bipolar structure is a high base resistance. A high base resistance results from the fact that the hole current supplied at the base contact flows through a portion of the substrate under the shallow-trench isolation where the resistivity is high and the well layer thickness is reduced. This results in a high voltage drop in the extrinsic base and an increase in noise. This also increases the forward voltage V_{BE} required for a given base current. Therefore, there is a need for a scheme that reduces the base resistance of the BJT.

### SUMMARY OF THE DISCLOSURE

Accordingly, the present invention is directed to a bipolar junction transistor based on a CMOS technology using the existing CMOS dopant profiles without added complexity.

An object of the present invention is to provide a bipolar junction transistor based on a CMOS technology, in which a reduced base current is provided without any changes to the profiles of a base and an emitter, and which increases a current gain β (the ratio of a collector current to a base current). Additionally, a shallow trench isolation STI between the emitter and the base is absent from the BJT, resulting in reduced base-resistance.

Additional advantages, objects, and features of the disclosure will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a bipolar junction transistor based on a CMOS technology includes a semiconductor substrate including an emitter region, a base having a first contact, and a collector having a second contact and a well plug; a first silicide film on the first contact; a second silicide film on the second contact; an optional third silicide film on the emitter, the third silicide film having a smaller width and/or length than the emitter region; a first silicide blocking layer on the semiconductor substrate between the first and second silicide films; and a second silicide blocking layer on the semiconductor substrate, at least between the first silicide film and the emitter.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principles of the disclosure. In the drawings:

FIG. 1 is a schematic plan view of a BJT structure used in a related art CMOS technology, and a cross-sectional view of the BJT structure across a line A-A′ shown in the schematic plan view.

FIG. 2 is a schematic plan view of a BJT structure used in a CMOS technology in accordance with a preferred embodiments of the present invention, and a cross-sectional view of the BJT structure across a line B-B′ shown in the schematic plan view.

FIG. 3 is a graph comparing the current gain of BJT structures of the present invention to that of the related art BJT structures.

FIG. 4 is a graph showing base currents I_{B} of a BJT with STI structures between the emitter, base, and collector, and a BJT without STI structures between the emitter, base, and collector plotted against a range of base-emitter forward voltages V_{BE}.

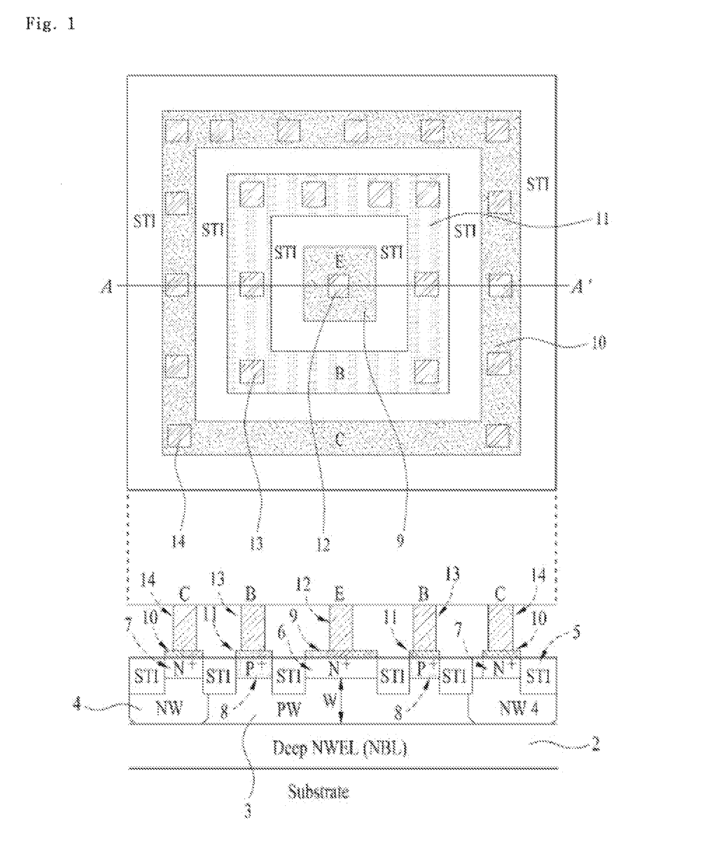

### DESCRIPTION OF SPECIFIC EMBODIMENTS

Reference will now be made in detail to the specific embodiments of the present invention, examples of which are illustrated in the accompanying drawings. Wherever possible, the same reference numbers will be used throughout the drawings to refer to the same or like parts.

A BJT for a CMOS base technology in accordance with a preferred embodiment of the present invention will be described in detail with reference to the attached drawings.

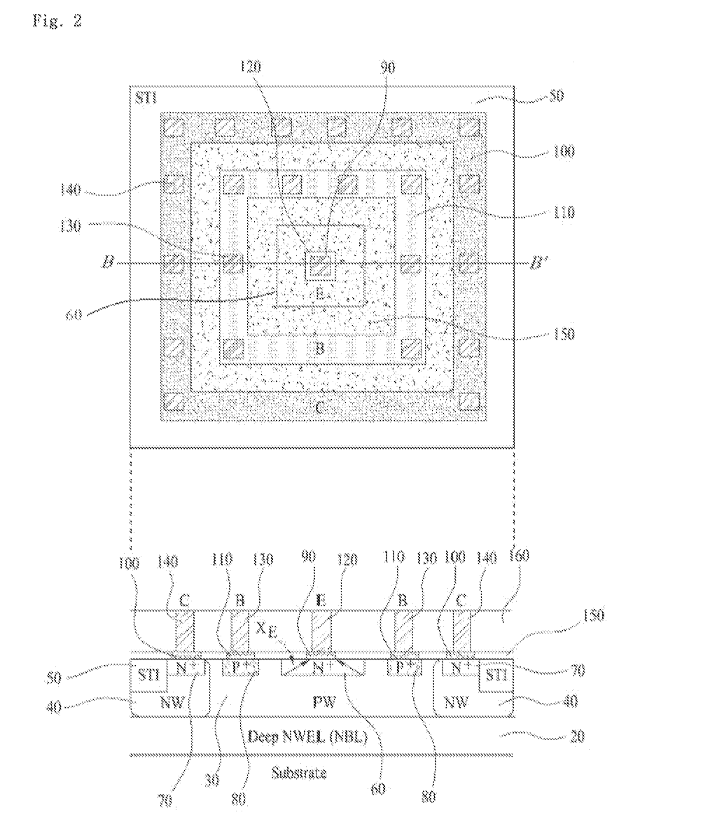

FIG. 2 illustrates a schematic plan view of a bipolar structure used in a CMOS technology in accordance with a preferred embodiment of the present invention, and a cross section thereof across a line B-B′ shown in the schematic plan view.

Referring to FIG. 2, there is a plurality of doping regions provided in an active region for forming an emitter, a base, and a collector therein. The structure shown in FIG. 2 illustrates an NPN BJT transistor fabricated on a p-type wafer. A PNP structure similar to that shown in FIG. 2 can be constructed by appropriate change in dopant polarities.

The collector C has a collector contact 70, a well plug 40 with the collector contact 70 therein, and a collector well 20. The collector well 20 is a deep n-type well structure, and the well plug 40 makes an electrical connection from the collector well 20 to the collector contact 70. The collector contact 70 is formed in the well plug 40. The n-type structures may include P, As, and/or Sb dopant atoms therein.

The base B has a base contact 80 and a base well 30. The base well 30 is a p-type well structure. The base contact 80 is formed in the base well 30. The p-type structures may include B dopant atoms therein.

The base well 30 also has the emitter region 60 of the emitter E formed therein. The emitter region 60 has the same conductivity type as the collector 20, and the base well 30 has a different conductivity type from the emitter region 60 and the collector well 20.

A key feature of the present invention lies in the silicide films 90, 100 and 110 provided on the emitter region 60, the collector contact 70 and the base contact 80, respectively. More specifically, each of the silicide films have areas that are smaller than the areas of the underlying emitter region 60, base contact 80 and collector contact 70, respectively, as seen in a plan view. For instance, the silicide film 90 on the emitter region 60 can have a smaller width and/or length than the emitter region 60. The silicide films 90, 100 and 110 may have widths and lengths that are 10-90% of the corresponding widths and lengths of the underlying emitter region 60, base contact 80 and collector contact 70, respectively. For example, silicide film 90 may have a width and a length that is 25-65% of the width and length of the underlying emitter region 60, and silicide films 100 and 110 may have widths and lengths that are 65-85% of the widths and lengths of the underlying contacts 70 and 80, respectively, or any value or range of values therein. Thus, the silicide films 90, 100 and 110 have smaller upper surface areas than the underlying emitter region 60, base contact 80 and collector contact 70, respectively.

In particular, the silicide film 90 does not completely cover the emitter region 60. Thus, a distance defined as X_{E} between an emitter-base metallurgical junction and the interface of the upper surface of the emitter region and the silicide film 90 on the emitter region 60 is increased. A silicide blocking layer 150 comprising silicon nitride or silicon oxide can be provided on peripheral portions of the upper surface of the emitter region 60, the base contact 80, and the collector contact 70 prior to forming silicide films 90, 100 and 110. The silicide blocking layer blocks silicide formation in areas between the emitter, the base and the collector. The silicide blocking layer 150 is formed on predetermined portions of the substrate, in order to prevent the silicide layers 90, 100, and 110 from being formed over those areas. The silicide blocking layer 150 is provided on the semiconductor substrate between the emitter and the base, and between the base and the collector, partially overlapping with the emitter region 60, the base contact 80, and the collector contact 70, thereby preventing the subsequently formed silicide layers 90, 100, and 110 from completely covering the emitter region 60, the collector contact 70, and the base contact 80, respectively. In one embodiment, the silicon blocking layer 150 also blocks the entire emitter region 60, in which case, the third silicide layer 90 is not formed. This is believed to further decrease the base current and further increase the gain.

In the present invention, a BJT structure is formed, in which the distance X_{E} is increased, resulting in a decreased base current. As the base current decreases, the current gain β, which is a ratio of the collector current to the base current, increases.

Additionally, the present invention does not require a shallow trench isolation (STI) film between the emitter region 60 and the base contact 80 within the base region 30, or between the base contact 80 and the collector contact 70 within the well plug 40. As a result, portions of the well 30 exist between the controller contact 70 and the base contact 80, as well as between the base contact 80 and the emitter region 60.

By forming the BJT without an STI between the emitter region 60 and the base contact 80, the base-resistance can be reduced.

The bipolar structure of the present invention will be described in more detail below. In following description, a first conductivity type is n-type and a second conductivity type is p-type. Alternatively, the first conductivity type can be a p-type and the second conductivity type can be n-type.

A semiconductor substrate includes a collector deep well 20 having a first conductivity type, a first conductivity type well plug 40, a base well 30 having a second conductivity, an emitter region 60, a base contact 80, and a collector contact 70. The emitter region 60 can be defined as a first doping region, the collector contact 70 can be defined as a second doping region, and the base contact 80 can be defined as a third doping region. The doping regions are formed such that they are spaced from one another in the semiconductor substrate.

The emitter region 60 and the collector contact 70 can be of the first conductivity type, and the base contact 80 can be of the second conductivity type. The emitter region 60 and the collector contact 70 can be formed simultaneously by injecting first conductivity type ions into the substrate using a same ion implantation mask. For instance, in embodiments where the first conductivity type is n-type, the emitter region 60 and the collector contact 70 may be formed by implanting P, As, and/or Sb dopant atoms into the semiconductor substrate at a predetermined energy and angle. Alternatively, the first conductivity type may be p-type, and the emitter region 60 and the collector contact 70 may be formed by implanting B dopant atoms into the semiconductor substrate at a predetermined energy and angle. Alternatively, the emitter region 60 and the collector contact 70 may be formed using separate implantation masks. The base contact 80 may be formed by implanted second conductivity type dopant atoms into the substrate in a separate implantation step, using a different ion implantation mask.

Silicide films 90, 100 and 110 and a silicide blocking layer 150 are formed on or over the semiconductor substrate. The silicide blocking layer 150 typically comprises an insulating film pattern covering peripheral portions of and portions of the substrate between the emitter region 60, the base contact 80 and the collector contact 70. The silicide blocking layer may be formed by depositing a silicon nitride film (e.g., by physical vapor deposition [PVD, e.g., sputtering] or chemical vapor deposition [CVD, e.g., plasma enhanced CVD or Low Pressure CVD]), or by depositing a silicon oxide film (e.g., by CVD of a silicon source, such as TEOS or silane [SiH4] and an oxygen source, such as dioxygen [O₂] and/or ozone [O₃]; or by coating a spin on glass [SOG], etc.).

The silicon nitride or silicon oxide film may be subsequently patterned to partially expose upper surfaces of the base contact 80 and the collector contact 70, and optionally, the emitter region 60. The portions of the upper surfaces of the emitter region 60, the base contact 80, and the collector contact 70 that are exposed may have widths and/or lengths equal to those of the silicide layers disclosed above.

The silicide films 90, 100 and 110 may be formed on the exposed portions of the upper surface of the emitter region 60, the base contact 80, and the collector contact 70, respectively. The silicide layer are typically formed by depositing a metal (e.g., tantalum [Ta], cobalt [Co], nickel [Ni], and/or titanium [Ti]) and annealing (e.g., by rapid thermal annealing at a temperature of about 600 to 1200° C.) the metal to form the silicide layers 90, 100 and 110. Unreacted metal on the silicide blocking layer 150 and structures other than exposed semiconductor substrate can then be selectively removed, as is known in the art.

The emitter region 60, the base contact 80, and the collector contact 70 may have dimensions which meet the base, emitter, and collector profiles required in CMOS technology.

For clarity, the silicide films 90, 100, and 110 are defined as an emitter silicide film 90 formed on the emitter region 60, a base silicide film 110 formed on the base contact 80, and a collector silicide film 100 formed on the collector contact 70. The emitter region 60 has the emitter silicide film 90 provided thereon having dimensions that are smaller than the those of the emitter region 60, the base contact 80 has the base silicide film 110 provided thereon having dimensions that are smaller than the those of the base contact 80, and the collector contact 70 can have the collector silicide film 100 provided thereon having dimensions that are smaller than those of the collector contact 70.

Thus, the areas of silicide films 90, 100, and 110 are smaller than those of the emitter region 60, the collector contact 70, and the base contact 80, respectively. Because the silicide film 90 has a smaller area than the emitter region 60, the distance X_{E} between the emitter-base metallurgical junction and the interface between the emitter region 60 and the silicide film 90 increases. For example, the area of the silicide film 90 may be from 10% to less than 50% of the area of the emitter region 60 (in a plan view, such as that shown in the top diagram of FIG. 2)

In the present invention, it is preferable that the silicide film 90 provided on the emitter region 60 is significantly smaller (has a significantly smaller width and length; i.e., a significantly smaller upper surface area) than the emitter region 60.

The silicide blocking layer 150 is adjacent to the silicide films 90, 100, and 110 on the semiconductor substrate, covering the regions of the semiconductor substrate that are not covered by the silicide films 90, 100 and 110. That is, the silicide blocking layer 150 is provided between the silicide films 90, 100, and 110 on the semiconductor substrate and on portions of the emitter region 60, the base contact 80, and the collector contact 70 that are not covered by the silicide films 90, 110, and 100.

The semiconductor device of the present invention also includes a top side insulating film 160 containing metal electrodes 120, 130, and 140 on or over the silicide blocking layer 150 and the silicide films 90, 100, and 110. The top side insulating film 160 may be formed by depositing one or more insulators such as silicon oxide, nitride, and/or oxynitride films over the semiconductor substrate after forming the silicide films 90, 110, and 100. Silicon oxide and silicon nitride films may be deposited as described herein, and silicon oxynitride films may be similarly deposited, as is known in the art. The top side insulating layer 160 may be subsequently patterned by forming a mask for defining contact holes over the silicide films 90, 110, and 100 in the insulating layer 160, and etching the exposed insulating layer 160. After the insulating layer 160 is patterned, a metal (e.g., W, Cu, or Al) may be deposited in the trenches by CVD (e.g., low pressure CVD, high pressure CVD, plasma enhanced CVD, etc.) or PVD (e.g., sputtering) to form metal electrodes 120, 130, and 140.

The metal electrodes 120, 130, and 140 include an emitter electrode 120, a base electrode 130, and a collector electrode 140. The emitter electrode 120 is in contact with the emitter silicide film 90, the base electrode 130 is in contact with the base silicide film 110, and the collector electrode 140 is in contact with the collector silicide film 100.

The structure of the present invention forms a collector path from the collector electrode 140 to the first conductivity type collector well 20 via the collector silicide film 100, the collector contact 70, and the first conductivity type well plug 40. Thus, the collector path includes the collector electrode 140, the collector silicide film 100, the first conductivity type well plug 40, and the first conductivity type collector well 20. The first conductivity type collector well 20 is a deep well structure, and the well plug 40 containing the collector contact 70 is a well for connecting the collector contact 70 to the collector well 20.

The base well 30 which is a second conductivity type well includes the emitter region 60 and the base contact 80 therein, and the base well 30 is operative as a base of an NPN junction. Thus, a base path is formed from the base electrode 130 to the base well 30 via the base silicide film 110 and the base contact 80.

As shown in FIG. 2, in the present invention, the shallow trench isolation film 50 is provided in the semiconductor substrate outside of the collector contact 70, to define the active region of the BJT.

In the device structure of the present invention, as shown in the schematic plan view of FIG. 2, the device structure has the emitter region 60 at a center thereof for the emitter, the base contact 80 surrounding the emitter E for the base, and the collector contact 70 surrounding the base B for the collector. Provided on the emitter region 60, the base contact 80, and the collector contact 70, there are the silicide films 90, 110, and 100 having smaller areas in comparison to the emitter region 60, the base contact 80, and the collector contact 70, respectively.

FIG. 2 of the present invention illustrates an NPN type transistor formed on a second conductivity type semiconductor substrate. Alternatively, the conductivity types can be changed, and FIG. 2 of the present invention can illustrate a PNP type transistor, if so desired. A PNP structure can be fabricated by appropriately changing the dopant polarities of the NPN type structure shown in FIG. 2, and selecting the proper impurities to be injected.

As FIG. 2 illustrates the NPN type transistor constructed on the p-type semiconductor substrate, the collector well 20, which may be a first conductivity type deep well, operates as a collector of an NPN junction, and may be used as an n-type buried layer (NBL) in a CMOS device.

As described above, the second conductivity type base well 30 operates as a base of the NPN junction, and also forms an NMOS body within the CMOS or a drain-extended region in a drain-extended PMOS.

The collector well 20 and the base well 30 are optimized to result in a minimum base width W_{b} and minimum Gummel number without compromising CMOS performance.

The first conductivity type well plug 40 makes a connection from the collector contact 70 to the collector well 20, and, in CMOS, acts as a PMOS body, or an extension of the drain in a drain-extended NMOS.

The emitter region 60 and the collector contact 70 can be made by the same process and using the same mask as NMOS source/drain regions in a corresponding CMOS manufacturing process, and the base contact 80 can be made by the same process and using the same mask as PMOS source/drain regions in the corresponding CMOS manufacturing process.

Thus, the present invention does not require a shallow trench isolation film between the emitter region 60, the base contact 80, and the collector contact 70. The dimensions of the silicide films 90, 100, and 110 have smaller widths and/or lengths than the emitter region 60, the collector contact 70, and the base contact 80, respectively. More specifically, the silicide films 90, 100, and 110 may have smaller upper surface areas than the upper surface areas of the emitter region 60, the collector contact 70, and the base contact 80, respectively, as shown in the schematic plan view of FIG. 2. The BJT structure of the present invention can be formed by using the same process for forming the CMOS devices on the same chip to form the BJT, without significant changes to the process.

The present invention can increase the hole path X_{E} as shown in FIG. 2 without additional costs by forming the silicide film 90 on the emitter region 60 with a smaller area than the emitter region 60 using the CMOS fabrication process. The increase in the hole path X_{E} results in a reduced base current and higher current gain.

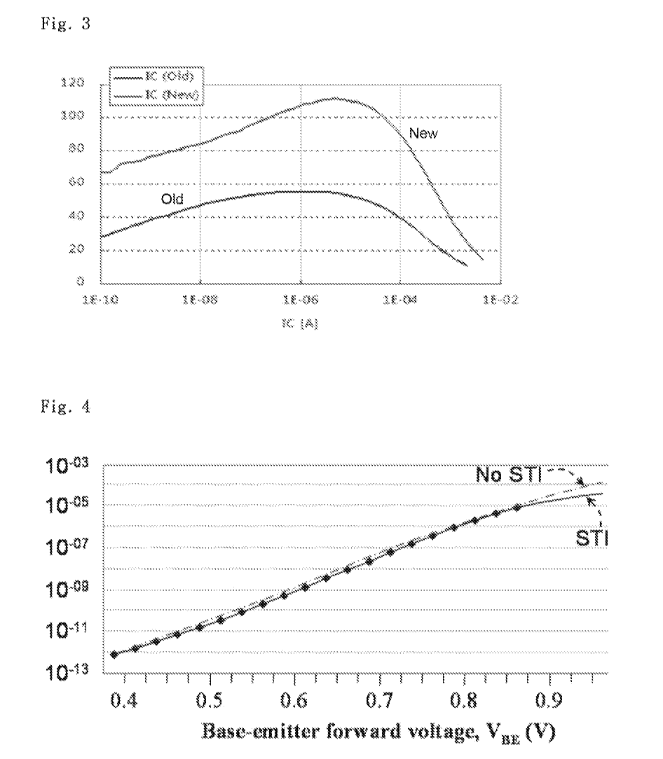

FIG. 3 illustrates a graph for comparing current gains of bipolar structures of the present invention and the related art. The bipolar structure of the present invention (labeled “New” in FIG. 3) shows a significant improvement of the current gain β over the related art structure (labeled “Old” in FIG. 3). Since the BJT structure of the present invention has a current gain β>100, it can be efficiently used for special applications, such as a band-gap reference circuit.

FIG. 4 is a graph showing comparison of base currents I_{B} of a BJT with STI structures between the emitter, base, and collector and a BJT without STI structures between the emitter, base, and collector, plotted over a range of base-emitter forward voltages V_{BE}. FIG. 4 demonstrates that the BJT structure of the present invention reduces a voltage drop in the base by reducing resistance to the base current in comparison to a related art BJT having STI structures between the emitter and base.

As has been described, the present bipolar junction transistor manufactured using a CMOS technology has at least the following advantages. Since the base current can be reduced while requiring no change of the profiles of the base and the emitter, the current gain β (the ratio of the collector current to the base current) can be increased, and a BJT structure can be provided that can be made using CMOS technology and that is suitable for a band-gap reference circuit. Additionally, the omission of the shallow trench isolation film between the emitter and the base reduces resistance to the base current and reduces the voltage drop in the base.

It will be apparent to those skilled in the art that various modifications and variations can be made in the present invention without departing from the spirit or scope of the inventions.

Thus, it is intended that the present invention covers the modifications and variations of this invention provided they come within the scope of the appended claims and their equivalents.

What is claimed is:

1. A bipolar junction transistor, comprising:
a semiconductor substrate including an emitter, a base having a first contact, and a collector having a second contact and a well plug;
a first silicide film on the first contact;
a second silicide film on the second contact;
a first silicide blocking layer on or over the semiconductor substrate between the first and second silicide films; and
a second silicide blocking layer formed on or over the semiconductor substrate, at least between the first silicide film and the emitter.

2. The bipolar junction transistor as claimed in claim 1, further comprising a third silicide film on the emitter, the third silicide film having a smaller area than that of the emitter.

3. The bipolar junction transistor as claimed in claim 2, further comprising a top side insulating film on the first, second, and third silicide films and the first and second silicide blocking layers.

4. The bipolar junction transistor as claimed in claim 3, further comprising:
a base electrode in the top side insulating film, over the first silicide film;
a collector electrode in the top side insulating film, over the second silicide film; and
an emitter electrode in the top side insulating film, over the third silicide film.

5. The bipolar junction transistor as claimed in claim 1, wherein the first silicide film has an area that is smaller than an area of the first contact, and
the second silicide film has an area that is smaller than an area of the second contact.

6. The bipolar junction transistor as claimed in claim 1, wherein the emitter and the second contact are of a first conductivity type, and the first contact is of a second conductivity type.

7. The bipolar junction transistor as claimed in claim 6, wherein the first conductivity type is N type, and the second conductivity type is P type.

8. The bipolar junction transistor as claimed in claim 1, wherein the first contact is provided within the base, and the second contact is provided within the well plug.

9. The bipolar junction transistor as claimed in claim 1, wherein the second silicide blocking layer is between the second and the third silicide films, and partially covers the emitter.

10. The bipolar junction transistor as claimed in claim 2, wherein the third silicide film has an area that is smaller than an area of the emitter.

11. The bipolar junction transistor as claimed in claim 10, wherein the area of the third silicide film increases a hole path within the emitter between an emitter-base metallurgical junction and an interface between the emitter and the third silicide film.

12. The bipolar junction transistor as claimed in claim 1, wherein the base further comprises a first well between the first contact and the emitter, and encompassed by the well plug.

13. The bipolar junction transistor as claimed in claim 12, wherein the collector further comprises a deep well below the first well, the well plug electrically connecting the second contact and the deep well.

14. The bipolar junction transistor as claimed in claim 10, wherein the bipolar junction transistor has a common-emitter current gain that is greater than 100.

15. The bipolar junction transistor as claimed in claim 1, further comprising a shallow trench isolation layer around the perimeter of the collector region, defining an active region of the bipolar junction transistor.

16. A method of forming a bipolar junction transistor, comprising:
forming an emitter, a base, and a collector within a semiconductor substrate, wherein the base has a first contact and the collector has a second contact;
forming a patterned silicide blocking layer over the semiconductor substrate by depositing a silicide blocking layer over the semiconductor substrate and patterning the silicide blocking layer to expose at least portions of the first contact and the second contact;
depositing a metal layer on or over the patterned silicide blocking layer and the exposed portions of the first contact and the second contact;
annealing the metal layer to form a first silicide film on or over the first contact, and a second silicide film on or over the second contact;
depositing an insulating layer over the patterned silicide blocking layer and the first and second silicide films; and
forming first, second, and third electrodes in the insulating layer, wherein the first electrode is on or over the first silicide film, the second electrode is on or over second silicide films, and the third electrode is on or over the emitter.

17. The method of claim 16, wherein the patterned silicide blocking layer exposes at least a portion of the emitter.

18. The method of claim 17, wherein annealing the metal layer forms a third silicide film on or over the emitter, wherein the third electrode is on or over the third silicide film.

19. The method of claim 18, wherein the first silicide film has an area smaller than an area of the first contact, the second silicide film has an area smaller than an area of the second contact, and the third silicide film has an area smaller than an area of the emitter.

20. The method of claim 17, wherein the smaller area of the third silicide film increases a hole path within the emitter between an emitter-base metallurgical junction and an interface between the emitter and the third silicide film.
